(19) United States
(12) Patent Application Publication
(10) Pub. No.: US 2024/0331913 A1
(43) Pub. Date: Oct. 3, 2024

(54) MULTILAYER ELECTRONIC COMPONENT

(71) Applicant: TDK CORPORATION, Tokyo (JP)

(72) Inventor: Yuki MATSUMOTO, Tokyo (JP)

(73) Assignee: TDK CORPORATION, Tokyo (JP)

(21) Appl. No.: 18/602,425

(22) Filed: Mar. 12, 2024

(30) Foreign Application Priority Data
Mar. 28, 2023 (JP) 2023-052098

(51) Int. Cl. H01F 17/00; H01F 27/28; H01F 27/29

(52) U.S. Cl. CPC H01F 17/0013; H01F 27/288; H01F 27/29; H01F 2017/0026

(57) ABSTRACT

An electronic component includes a first inductor, a second inductor, and a shield structure. Each of the first inductor and the second inductor includes a plurality of inductor conductor layers. The plurality of inductor conductor layers include a first conductor layer closest to a first surface of a stack and a second conductor layer closest to a second surface of the stack. The shield structure is arranged between the first inductor and the second inductor when viewed in a stacking direction, and is arranged between the second conductor layer of each of the first inductor and the second inductor and the first surface of the stack.

### CROSS REFERENCE TO RELATED APPLICATIONS

This application claims the benefit of Japanese Priority Patent Application No. 2023-52098 filed on Mar. 28, 2023, the entire contents of which are incorporated herein by reference.

### BACKGROUND OF THE INVENTION

### 1. Field of the Invention

The present invention relates to a multilayer electronic component including a plurality of inductors.

### 2. Description of the Related Art

Compact mobile communication apparatuses are generally configured to include a common antenna for a plurality of applications that use different systems and have different service frequency bands, and to use a branching filter to separate a plurality of signals for this antenna to transmit and receive.

A branching filter for separating a first signal of a frequency within a first frequency band and a second signal of a frequency within a second frequency band higher than the first frequency band from each other typically includes a common port, a first signal port, a second signal port, a first filter provided in a first signal path leading from the common port to the first signal port, and a second filter provided in a second signal path leading from the common port to the second signal port. As the first and second filters, LC resonators each including an inductor and a capacitor are used, for example.

The recent market demands for reductions in size and footprint of the compact mobile communication apparatuses and also requires downsizing of branching filters for use in those communication apparatuses. As a branching filter suitable for downsizing, a branching filter including a stack including a plurality of dielectric layers and a plurality of conductor layers stacked together is known.

An inductor used in an LC resonator generates leakage magnetic flux. Thus, if electromagnetic coupling between the inductor of the first filter and the inductor of the second filter is too strong, desired characteristics may not be able to be achieved.

JP 7-326517 A1 discloses a multilayer inductor with a shield wall provided around a coil pattern. In this multilayer inductor, in a stacking direction of a stack, a top end of a coil and a top end of the shield wall are arranged at the same position, and a bottom end of the coil and a bottom end of the shield wall are arranged at the same position.

Here, assuming that such a shield structure as in JP 7-326517 A1 is provided between two inductors in a branching filter including a stack, in order to suppress coupling between the two inductors. If the branching filter is downsized, the distance between each of the two inductors and the shield structure is reduced. In this case, floating capacitance may be generated between each of the two inductors and the shield structure, and desired characteristics may not be able to be achieved.

The foregoing problem is applied not only to branching filters but also to multilayer electronic components in general that include a plurality of inductors.

### SUMMARY OF THE INVENTION

An objective of the present invention is to provide a multilayer electronic component that includes a shield structure provided between two inductors and that can achieve desired characteristics.

A multilayer electronic component of the present invention includes a first inductor, a second inductor, a shield structure, and a stack that integrates the first inductor, the second inductor, and the shield structure, the stack including a plurality of dielectric layers stacked together. The stack includes a first surface and a second surface located at both ends in a stacking direction of the plurality of dielectric layers. Each of the first inductor and the second inductor includes a plurality of inductor conductor layers, the plurality of inductor conductor layers being arranged at a certain interval in the stacking direction. The plurality of inductor conductor layers include a first conductor layer closest to the first surface and a second conductor layer closest to the second surface. The shield structure is arranged between the first inductor and the second inductor when viewed in the stacking direction, and is arranged between the second conductor layer and the first surface in the stacking direction.

In the multilayer electronic component of the present invention, the shield structure is arranged between the second conductor layer of each of the first and second inductors and the first surface in the stacking direction. With this, the present invention allows desired characteristics to be achieved.

Other and further objects, features and advantages of the present invention will appear more fully from the following description.

### BRIEF DESCRIPTION OF THE DRAWINGS

FIG. 1 is a circuit diagram showing an example of a circuit configuration of a multilayer electronic component according to an embodiment of the present invention.

FIG. 2 is an external perspective view showing the multilayer electronic component according to the embodiment of the present invention.

FIGS. 3A to 3C are explanatory diagrams showing respective patterned surfaces of first to third dielectric layers in a stack in the multilayer electronic component according to the embodiment of the present invention.

FIGS. 4A to 4C are explanatory diagrams showing respective patterned surfaces of fourth to sixth dielectric layers in the stack in the multilayer electronic component according to the embodiment of the present invention.

FIGS. 5A to 5C are explanatory diagrams showing respective patterned surfaces of seventh to ninth dielectric layers in the stack in the multilayer electronic component according to the embodiment of the present invention.

FIG. 6A is an explanatory diagram showing a patterned surface of a tenth dielectric layer in the stack in the multilayer electronic component according to the embodiment of the present invention.

FIG. 6B is an explanatory diagram showing respective patterned surfaces of eleventh and twelfth dielectric layers in the stack in the multilayer electronic component according to the embodiment of the present invention.

FIG. 6C is an explanatory diagram showing a patterned surface of a thirteenth dielectric layer in the stack in the multilayer electronic component according to the embodiment of the present invention.

FIGS. 7A to 7C are explanatory diagrams showing respective patterned surfaces of fourteenth to sixteenth dielectric layers in the stack in the multilayer electronic component according to the embodiment of the present invention.

FIGS. 8A to 8C are explanatory diagrams showing respective patterned surfaces of seventeenth to nineteenth dielectric layers in the stack in the multilayer electronic component according to the embodiment of the present invention.

FIGS. 9A to 9C are explanatory diagrams showing respective patterned surfaces of twentieth to twenty-second dielectric layers in the stack in the multilayer electronic component according to the embodiment of the present invention.

FIGS. 10A and 10B are explanatory diagrams showing respective patterned surfaces of twenty-third and twenty-fourth dielectric layers in the stack in the multilayer electronic component according to the embodiment of the present invention.

FIG. 11 is a perspective view showing an inside of the stack in the multilayer electronic component according to the embodiment of the present invention.

FIG. 12 is a plan view showing the inside of the stack in the multilayer electronic component according to the embodiment of the present invention.

FIG. 13 is a characteristic chart showing an example of pass attenuation characteristics between a common terminal and a first signal terminal in the embodiment of the present invention.

FIG. 14 is a characteristic chart showing an example of return attenuation characteristics of the first signal terminal in the embodiment of the present invention.

FIG. 15 is a characteristic chart showing an example of pass attenuation characteristics between the common terminal and a second signal terminal in the embodiment of the present invention.

FIG. 16 is a characteristic chart showing an example of return attenuation characteristics of the second signal terminal in the embodiment of the present invention.

FIG. 17 is a characteristic chart showing an example of pass attenuation characteristics between the common terminal and a third signal terminal in the embodiment of the present invention.

FIG. 18 is a characteristic chart showing an example of return attenuation characteristics of the third signal terminal in the embodiment of the present invention.

FIG. 19 is a characteristic chart showing an example of return attenuation characteristics of the common terminal in the embodiment of the present invention.

FIG. 20 is a characteristic chart showing an example of frequency characteristics of isolation between the first signal terminal and the second signal terminal in the embodiment of the present invention.

FIG. 21 is a characteristic chart showing an example of frequency characteristics of isolation between the second signal terminal and the third signal terminal in the embodiment of the present invention.

FIG. 22 is a characteristic chart showing an example of frequency characteristics of isolation between the third signal terminal and the first signal terminal in the embodiment of the present invention.

### DETAILED DESCRIPTION OF THE PREFERRED EMBODIMENTS

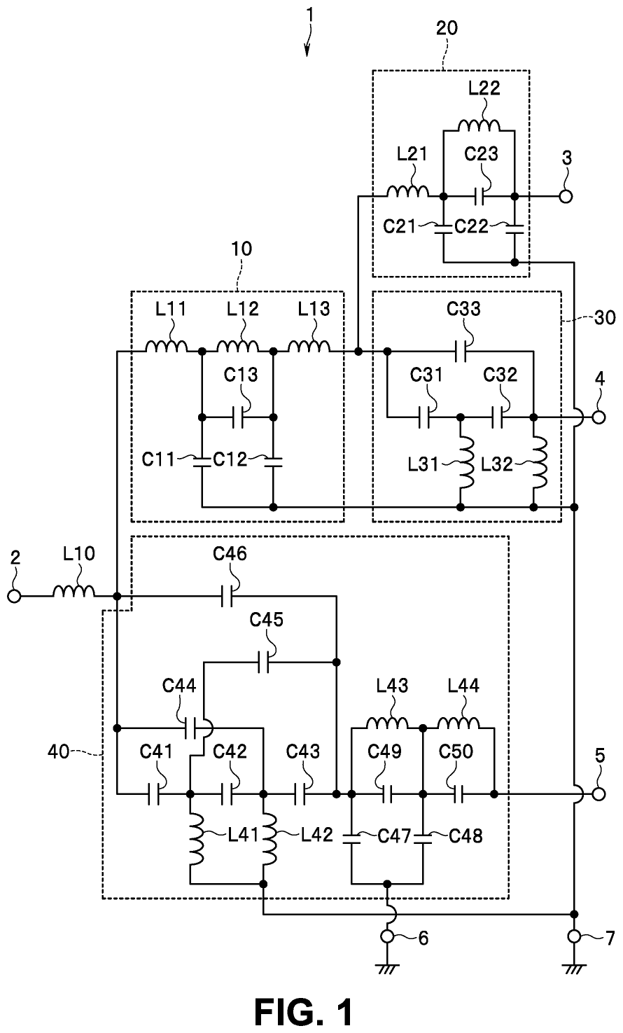

An embodiment of the present invention will now be described in detail with reference to the drawings. First, a configuration of a multilayer electronic component (hereinafter simply referred to as an electronic component) 1 according to an embodiment of the present invention will be outlined with reference to FIG. 1. FIG. 1 is a circuit diagram showing an example of a circuit configuration of the electronic component 1. FIG. 1 shows a branching filter (triplexer) as an example of the electronic component 1.

The electronic component 1 includes a common terminal 2, a first signal terminal 3, a second signal terminal 4, a third signal terminal 5, and ground terminals 6 and 7. The first signal terminal 3 selectively passes a signal of a frequency within a first passband. The second signal terminal 4 selectively passes a signal of a frequency within a second passband higher than the first passband. The third signal terminal 5 selectively passes a signal of a frequency within a third passband higher than the second passband. Each of the ground terminals 6 and 7 is connected to the ground.

The electronic component 1 further includes a first filter circuit 10, a second filter circuit 20, a third filter circuit 30, and a fourth filter circuit 40. The first filter circuit 10 is provided between the common terminal 2 and the first and second signal terminals 3 and 4, in a circuit configuration. The second filter circuit 20 is provided between the first filter circuit 10 and the first signal terminal 3, in the circuit configuration. The third filter circuit 30 is provided between the first filter circuit 10 and the second signal terminal 4, in the circuit configuration. The fourth filter circuit 40 is provided between the common terminal 2 and the third signal terminals 5, in the circuit configuration. Note that, in the present application, the expression “in the (a) circuit configuration” is used to indicate an arrangement in a circuit diagram, not an arrangement in physical configuration.

The first filter circuit 10 is a filter configured to selectively pass a signal of a frequency band including the first passband and the second passband but not including the third passband. The second filter circuit 20 is a filter configured to selectively pass a signal of a frequency band including the first passband but not including the second passband. The third filter circuit 30 is a filter configured to selectively pass a signal of a frequency band including the second passband but not including the first passband. The fourth filter circuit 40 is a filter configured to selectively pass a signal of a frequency band including the third passband but not including the first passband nor the second passband.

Each of the first and second filter circuits 10 and 20 may be a low-pass filter. The third filter circuit 30 may be a high-pass filter. The fourth filter circuit 40 may be a band-pass filter including a high-pass filter and a low-pass filter connected in series.

The electronic component 1 further includes a first path connecting the common terminal 2 and the first signal terminal 3, a second path connecting the common terminal 2 and the second signal terminal 4, and a third path connecting the common terminal 2 and the third signal terminal 5. Each of the first and second paths includes the same path from the common terminal 2 to a branch point where the path branches into the second filter circuit 20 and the third filter circuit 30.

The first filter circuit 10 is provided on a path constituting a part of each of the first and second paths. The second and third filter circuits 20 and 30 are provided at a subsequent stage of the first filter circuit 10. The second filter circuit 20 is provided on the first path. The third filter circuit 30 is provided on the second path. The fourth filter circuit 40 is provided on the third path.

A first signal of a frequency within the first passband input to the common terminal 2 selectively passes the first path, specifically, the first and second filter circuits 10 and 20, and is output from the first signal terminal 3. A second signal of a frequency within the second passband input to the common terminal 2 selectively passes the second path, specifically, the first and third filter circuits 10 and 30, and is output from the second signal terminal 4. A third signal of a frequency within the third passband input to the common terminal 2 selectively passes the third path, specifically, the fourth filter circuit 40, and is output from the third signal terminal 5. In such a manner, the electronic component 1 separates the first to third signals.

Next, an example of a circuit configuration of the electronic component 1 will be described with reference to FIG. 1. The electronic component 1 further includes an inductor L10 having one end connected to the common terminal 2. Each of the first and fourth filter circuits 10 and 40 is connected to the other end of the inductor L10.

The first filter circuit 10 includes inductors L11, L12, and L13, and capacitors C11, C12, and C13. One end of the inductor L11 is connected to the other end of the inductor L10. One end of the inductor L12 is connected to the other end of the inductor L11. One end of the inductor L13 is connected to the other end of the inductor L12.

One end of the capacitor C11 is connected to a connection point between the inductor L11 and the inductor L12. One end of the capacitor C12 is connected to a connection point between the inductor L12 and the inductor L13. The other end of each of the capacitors C11 and C12 is connected to the ground terminal 7. The capacitor C13 is connected in parallel with the inductor L12.

Each of the second and third filter circuits 20 and 30 is connected to the other end of the inductor L13 of the first filter circuit 10.

The second filter circuit 20 includes inductors L21 and L22, and capacitors C21, C22, and C23. One end of the inductor L21 is connected to the other end of the inductor L13 of the first filter circuit 10. One end of the inductor L22 is connected to the other end of the inductor L21. The other end of the inductor L22 is connected to the first signal terminal 3.

One end of the capacitor C21 is connected to a connection point between the inductor L21 and the inductor L22. One end of the capacitor C22 is connected to the other end of the inductor L22. The other end of each of the capacitors C21 and C22 is connected to the ground terminal 7. The capacitor C23 is connected in parallel with the inductor L22.

The third filter circuit 30 includes inductors L31 and L32, and capacitors C31, C32, and C33. One end of the capacitor C31 is connected to the other end of the inductor L13 of the first filter circuit 10. One end of the capacitor C32 is connected to the other end of the capacitor C31. The other end of capacitor C32 is connected to the second signal terminal 4.

One end of the capacitor C33 is connected to the one end of the capacitor C31. The other end of the capacitor C33 is connected to the other end of the capacitor C32.

One end of the inductor L31 is connected to a connection point between the capacitor C31 and the capacitor C32. One end of the inductor L32 is connected to the other end of the capacitor C32. The other end of each of the inductors L31 and L32 is connected to the ground terminal 7.

The fourth filter circuit 40 includes inductors L41, L42, L43, and L44, and capacitors C41, C42, C43, C44, C45, C46, C47, C48, C49, and C50. One end of the capacitor C41 is connected to the other end of the inductor L10. One end of the capacitor C42 is connected to the other end of the capacitor C41. One end of the capacitor C43 is connected to the other end of the capacitor C42.

One end of the capacitor C44 is connected to the one end of the capacitor C41. The other end of the capacitor C44 is connected to a connection point between the capacitor C42 and the capacitor C43. One end of the capacitor C45 is connected to a connection point between the capacitor C41 and the capacitor C42. The other end of the capacitor C45 is connected to the other end of the capacitor C43. One end of the capacitor C46 is connected to the one end of the capacitor C41. The other end of the capacitor C46 is connected to the other end of the capacitor C43.

One end of the inductor L41 is connected to the connection point between the capacitor C41 and the capacitor C42. One end of the inductor L42 is connected to the connection point between the capacitor C42 and the capacitor C43. The other end of each of the inductors L41 and L42 is connected to the ground terminal 7.

One end of the inductor L43 is connected to the other end of the capacitor C43. One end of the inductor L44 is connected to the other end of the inductor L43. The other end of the inductor L44 is connected to the third signal terminal 5.

One end of the capacitor C47 is connected to the one end of the inductor L43. One end of the capacitor C48 is connected to a connection point between the inductor L43 and the inductor L44. The other end of each of the capacitors C47 and C48 is connected to the ground terminal 6.

The capacitor C49 is connected in parallel with the inductor L43. The capacitor C50 is connected in parallel with the inductor L44.

In the fourth filter circuit 40, the inductors L41 and L42, and the capacitors C41 to C46 compose a high-pass filter. In the fourth filter circuit 40, the inductors L43 and L44, and the capacitors C47 to C50 compose a low-pass filter.

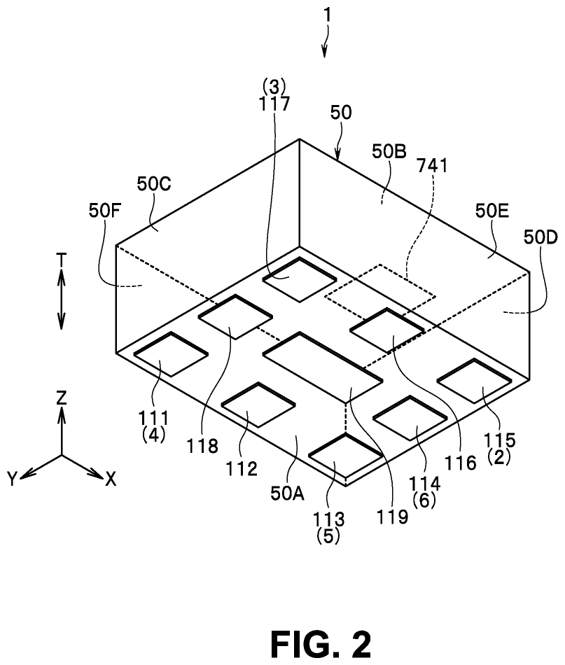

Next, other configurations of the electronic component 1 will be described with reference to FIG. 2. FIG. 2 is an external perspective view showing the electronic component 1.

The electronic component 1 further includes a stack 50 including a plurality of dielectric layers stacked together and a plurality of conductors (a plurality of conductor layers and a plurality of through holes). The common terminal 2, the first to third signal terminals 3 to 5, the ground terminals 6 and 7, the first to fourth filter circuits 10, 20, 30, and 40, and the inductor L10 are integrated with the stack 50.

The stack 50 includes a first surface 50A and a second surface 50B located at both ends in a stacking direction T of the plurality of dielectric layers, and four side surfaces 50C to 50F connecting the first surface 50A and the second surface 50B. The side surfaces 50C and 50D are opposite to each other. The side surfaces 50E and 50F are opposite to each other. The side surfaces 50C to 50F are perpendicular to the second surface 50B and the first surface 50A.

Here, X, Y, and Z directions are defined as shown in FIG. 2. The X, Y, and Z directions are orthogonal to one another. In the present embodiment, a direction parallel to the stacking direction T will be referred to as the Z direction. The opposite directions to the X, Y, and Z directions are defined as −X, −Y, and −Z directions, respectively. The expression “when viewed in the stacking direction T” means that an object is viewed from a position away in the Z direction or the −Z direction.

As shown in FIG. 2, the first surface 50A is located at the end of the stack 50 in the −Z direction. The first surface 50A is also a bottom surface of the stack 50. The second surface 50B is located at the end of the stack 50 in the Z direction. The second surface 50B is also a top surface of the stack 50. The side surface 50C is located at the end of the stack 50 in the −X direction. The side surface 50D is located at the end of the stack 50 in the X direction. The side surface 50E is located at the end of the stack 50 in the −Y direction. The side surface 50F is located at the end of the stack 50 in the Y direction.

The electronic component 1 further includes electrodes 111, 112, 113, 114, 115, 116, 117, 118, and 119 provided on the first surface 50A of the stack 50. The electrode 111 is arranged near a corner where the first surface 50A and the side surfaces 50C and 50F intersect. The electrode 113 is arranged near a corner where the first surface 50A and the side surfaces 50D and 50F intersect. The electrode 115 is arranged near a corner where the first surface 50A and the side surfaces 50D and 50E intersect. The electrode 117 is arranged near a corner where the first surface 50A and the side surfaces 50C and 50E intersect.

The electrode 112 is arranged between the electrode 111 and the electrode 113. The electrode 114 is arranged between the electrode 113 and the electrode 115. The electrode 116 is arranged between the electrode 115 and the electrode 117. The electrode 118 is arranged between the electrode 111 and the electrode 117. The electrode 119 is arranged at the center of the first surface 50A.

The electrode 111 corresponds to the second signal terminal 4, the electrode 113 corresponds to the third signal terminal 5, the electrode 114 corresponds to the ground terminal 6, the electrode 115 corresponds to the common terminal 2, and the electrode 117 corresponds to the first signal terminal 3. The ground terminal 7 includes the electrodes 112, 116, 118, and 119. Hence, the common terminal 2, the first to third signal terminals 3 to 5, and the ground terminals 6 and 7 are provided on the first surface 50A of the stack 50.

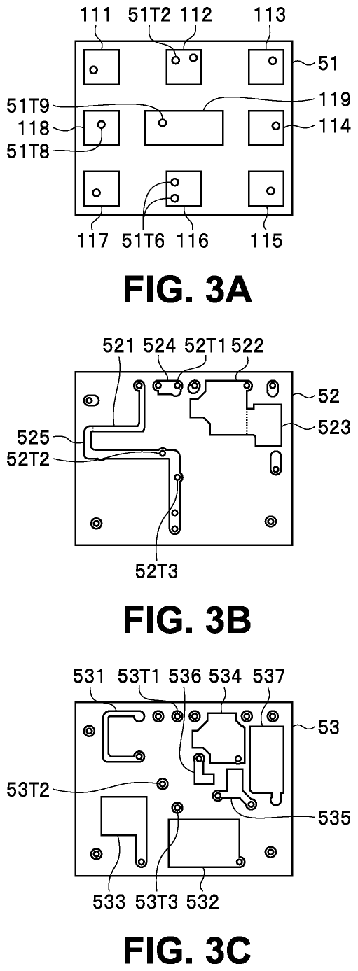

Next, an example of the plurality of dielectric layers and the plurality of conductors composing the stack 50 will be described with reference to FIG. 3A to FIG. 10B. In this example, the stack 50 includes twenty four dielectric layers stacked together. Hereinafter, the twenty four dielectric layers will be referred to as first to twenty-fourth dielectric layers in the order from bottom to top. The first to twenty-fourth dielectric layers are denoted by reference numerals 51 to 74, respectively.

In FIG. 3A to FIG. 9C, each circle represents a through hole. The dielectric layers 51 to 72 each have a plurality of through holes. The through holes are each formed by filling a hole intended for a through hole with a conductive paste. Each of the plurality of through holes is connected to an electrode, a conductor layer, or another through hole. In the following, a connection relation between each of the plurality of thorough holes and an electrode, a conductor layer, or another through hole is described as a connection relation in a state where the first to twenty-fourth dielectric layers 51 to 74 are stacked together.

In FIG. 3A to FIG. 10B, a plurality of specific conductor layers of the plurality of conductor layers and a plurality of specific through holes of the plurality of through holes are each denoted by a reference numeral.

FIG. 3A shows a patterned surface of the first dielectric layer 51. The electrodes 111 to 119 are formed on the patterned surface of the dielectric layer 51.

In FIG. 3A, a through hole denoted by a reference numeral 51T2 is connected to the electrode 112. Note that, in the following description, a through hole denoted by a reference numeral 52T2 is simply referred to as a through hole 52T2. Such a manner for the through hole 52T2 similarly applies to through holes denoted by reference numerals other than the through hole 52T2.

Two through holes 51T6 shown in FIG. 3A are connected to the electrode 116. Through holes 51T8 and 51T9 are connected respectively to the electrodes 118 and 119.

FIG. 3B shows a patterned surface of the second dielectric layer 52. Four conductor layers denoted by reference numerals 521, 522, 523, and 524 are formed on the patterned surface of the dielectric layer 52. Note that, in the following description, a conductor layer denoted by a reference numeral 521 is simply referred to as a conductor layer 521. Such a manner for the conductor layer 521 similarly applies to conductor layers denoted by reference numerals other than the conductor layer 521.

The conductor layer 521 is an inductor conductor layer and is connected to the conductor layer 525. The conductor layer 523 is connected to the conductor layer 522. In FIG. 3B, the boundary between two conductor layers is indicated by a dotted line. Note that, also in a drawing similar to FIG. 3B to be referenced to in the following description, the boundary between two conductor layers is indicated by a dotted line.

The through hole 51T2 and a through hole 52T1 shown in FIG. 3B are connected to the conductor layer 524. The through holes 51T6 and 51T8 and through holes 52T2 and 52T3 shown in FIG. 3B are connected to the conductor layer 525.

FIG. 3C shows a patterned surface of the third dielectric layer 53. An inductor conductor layer 531 and conductor layers 532, 533, 534, 535, 536, and 537 are formed on the patterned surface of the dielectric layer 53. The through holes 52T1, 52T2, and 52T3 are connected respectively to through holes 53T1, 53T2, and 53T3 shown in FIG. 3C.

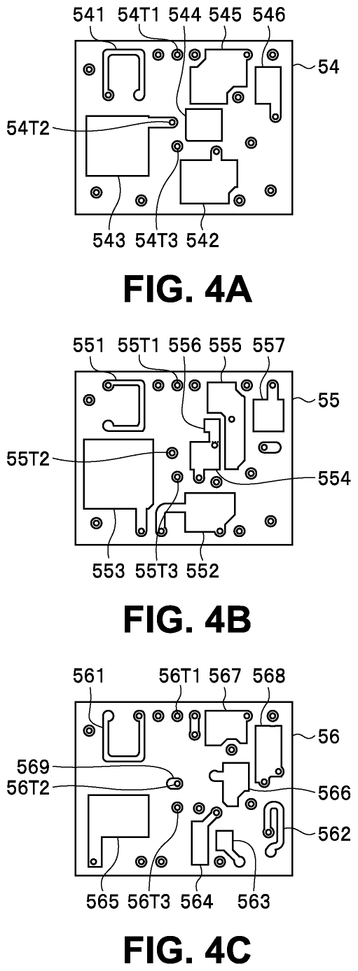

FIG. 4A shows a patterned surface of the fourth dielectric layer 54. An inductor conductor layer 541 and conductor layers 542, 543, 544, 545, and 546 are formed on the patterned surface of the dielectric layer 54. The through holes 53T1 and 53T3 are connected respectively to through holes 54T1 and 54T3 shown in FIG. 4A. The through hole 53T2 and a through hole 54T2 shown in FIG. 4A are connected to the conductor layer 543.

FIG. 4B shows a patterned surface of the fifth dielectric layer 55. An inductor conductor layer 551 and conductor layers 552, 553, 554, 555, 556, and 557 are formed on the patterned surface of the dielectric layer 55. The conductor layer 556 is connected to the conductor layer 554. The through holes 54T1, 54T2, and 54T3 are connected respectively to through holes 55T1, 55T2, and 55T3 shown in FIG. 4B.

FIG. 4C shows a patterned surface of the sixth dielectric layer 56. Inductor conductor layers 561 and 562 and conductor layers 563, 564, 565, 566, 567, 568, and 569 are formed on the patterned surface of the dielectric layer 56. The through holes 55T1 and 55T3 are connected respectively to through holes 56T1 and 56T3 shown in FIG. 4C. The through hole 55T2 and a through hole 56T2 shown in FIG. 4C are connected to the conductor layer 569.

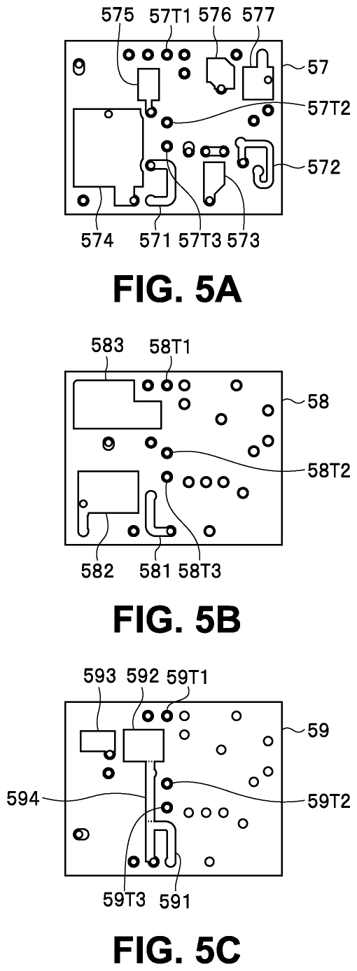

FIG. 5A shows a patterned surface of the seventh dielectric layer 57. Inductor conductor layers 571 and 572 and conductor layers 573, 574, 575, 576, and 577 are formed on the patterned surface of the dielectric layer 57. The through holes 56T1, 56T2, and 56T3 are connected respectively to through holes 57T1, 57T2, and 57T3 shown in FIG. 5A.

FIG. 5B shows a patterned surface of the eighth dielectric layer 58. An inductor conductor layer 581 and conductor layers 582 and 583 are formed on the patterned surface of the dielectric layer 58. The through holes 57T1, 57T2, and 57T3 are connected respectively to through holes 58T1, 58T2, and 58T3 shown in FIG. 5B.

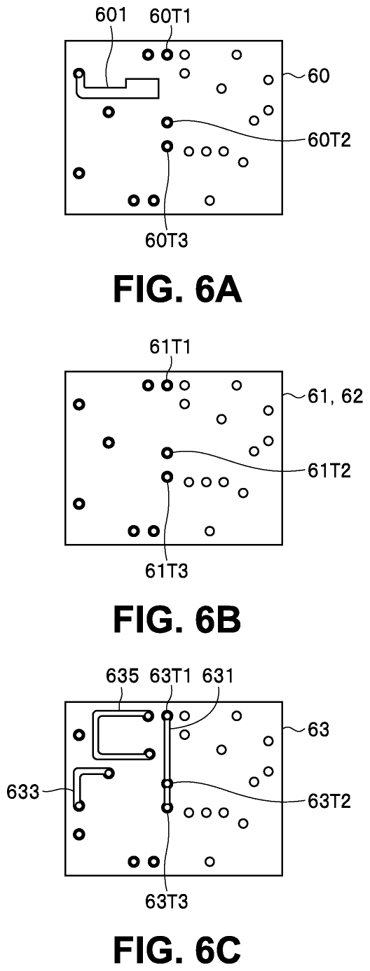

FIG. 5C shows a patterned surface of the ninth dielectric layer 59. An inductor conductor layer 591 and conductor layers 592, 593, and 594 are formed on the patterned surface of the dielectric layer 59. Each of the conductor layers 591 and 592 is connected to the conductor layer 594. The through holes 58T1, 58T2, and 58T3 are connected respectively to through holes 59T1, 59T2, and 59T3 shown in FIG. 5C. FIG. 6A shows a patterned surface of the tenth dielectric layer 60. A conductor layer 601 is formed on the patterned surface of the dielectric layer 60. The through holes 59T1, 59T2, and 59T3 are connected respectively to through holes 60T1, 60T2, and 60T3 shown in FIG. 6A.

FIG. 6B shows a patterned surface of each of the eleventh and twelfth dielectric layers 61 and 62. The through holes 60T1, 60T2, and 60T3 are connected respectively to through holes 61T1, 61T2, and 61T3 formed in the dielectric layer 61. In the dielectric layers 61 and 62, upper and lower adjacent through holes of the same reference numerals are connected to each other.

FIG. 6C shows a patterned surface of the thirteenth dielectric layer 63. A conductor layer 631 and inductor conductor layers 633 and 635 are formed on the patterned surface of the dielectric layer 63. The through holes 61T1, 61T2, and 61T3 formed in the dielectric layer 62 and through holes 63T1, 63T2, and 63T3 shown in FIG. 6C are connected to the conductor layer 631.

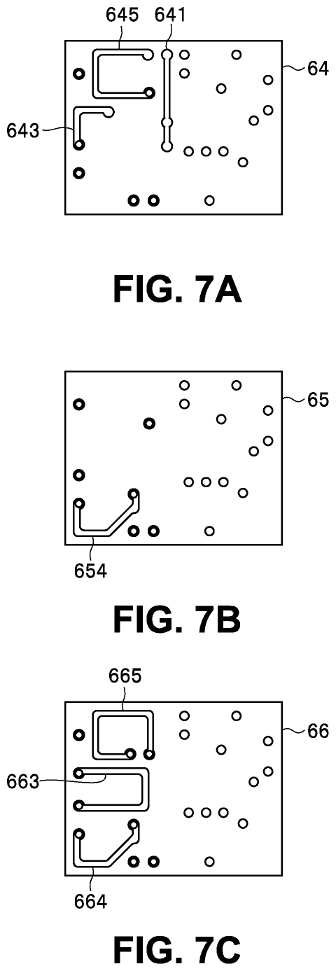

FIG. 7A shows a patterned surface of the fourteenth dielectric layer 64. A conductor layer 641 and inductor conductor layers 643 and 645 are formed on the patterned surface of the dielectric layer 64. The through holes 63T1, 63T2, and 63T3 are connected to the conductor layer 641.

FIG. 7B shows a patterned surface of the fifteenth dielectric layer 65. An inductor conductor layer 654 is formed on the patterned surface of the dielectric layer 65. FIG. 7C shows a patterned surface of the sixteenth dielectric layer 66. Inductor conductor layers 663, 664, and 665 are formed on the patterned surface of the dielectric layer 66.

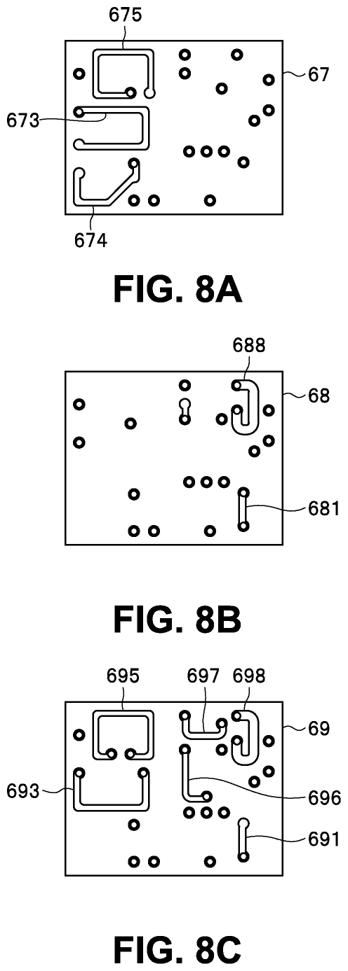

FIG. 8A shows a patterned surface of the seventeenth dielectric layer 67. Conductor layers 673, 674, and 675 are formed on the patterned surface of the dielectric layer 67. FIG. 8B shows a patterned surface of the eighteenth dielectric layer 68. Inductor conductor layers 681 and 688 are formed on the patterned surface of the dielectric layer 68. FIG. 8C shows a patterned surface of the nineteenth dielectric layer 69. Conductor layers 691, 693, 695, 696, 697, and 698 are formed on the patterned surface of the dielectric layer 69.

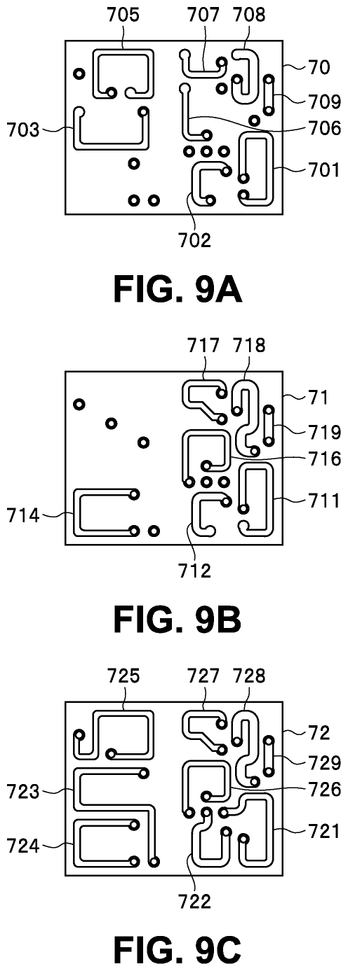

FIG. 9A shows a patterned surface of the twentieth dielectric layer 70.

Inductor conductor layers 701, 702, 703, 705, 706, 707, 708, and 709 are formed on the patterned surface of the dielectric layer 70. FIG. 9B shows a patterned surface of the twenty-first dielectric layer 71. Conductor layers 711, 712, 714, 716, 717, 718, and 719 are formed on the patterned surface of the dielectric layer 71. FIG. 9C shows a patterned surface of the twenty-second dielectric layer 72. Conductor layers 721, 722, 723, 724, 725, 726, 727, 728, and 729 are formed on the patterned surface of the dielectric layer 72.

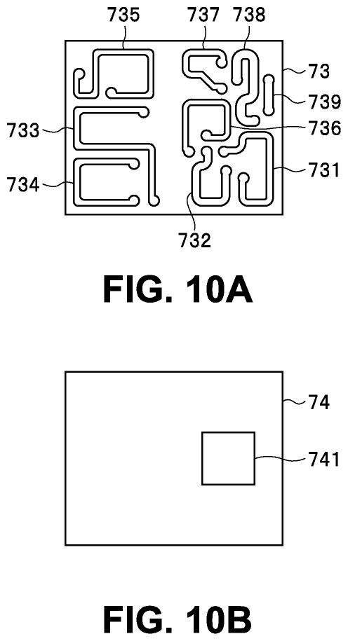

FIG. 10A shows a patterned surface of the twenty-third dielectric layer 73. Inductor conductor layers 731, 732, 733, 734, 735, 736, 737, 738, and 739 are formed on the patterned surface of the dielectric layer 73. FIG. 10B shows a patterned surface of the twenty-fourth dielectric layer 74. A mark 741 is formed on the patterned surface of the dielectric layer 74.

The stack 50 shown in FIG. 2 includes the first to twenty-fourth dielectric layers 51 to 74 stacked together such that the patterned surface of the first dielectric layer 51 serves as the first surface 50A of the stack 50 and the surface of the twenty-fourth dielectric layer 74 opposite to the patterned surface thereof serves as the second surface 50B of the stack 50.

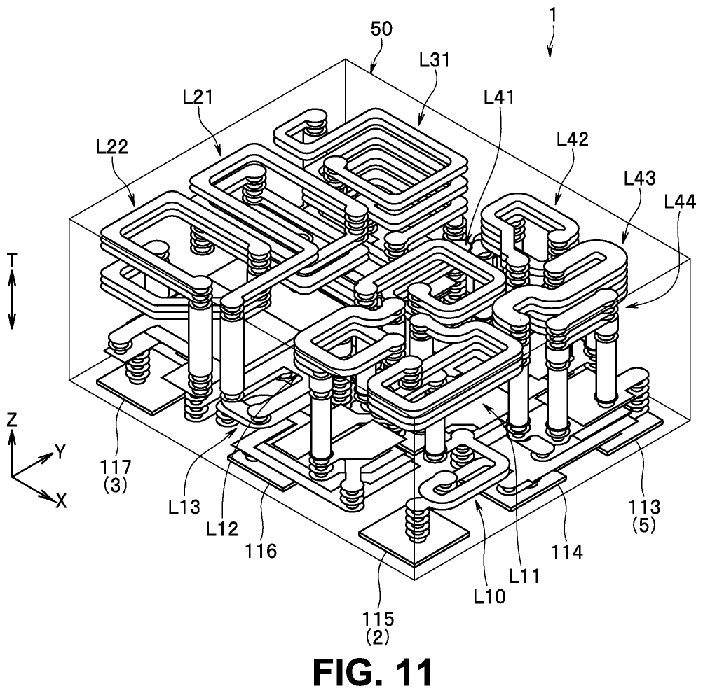

FIG. 11 shows an inside of the stack 50 including the first to twenty-fourth dielectric layers 51 to 74 stacked together. As shown in FIG. 11, the plurality of conductor layers and the plurality of through holes shown in FIG. 3A to FIG. 10A are stacked together inside the stack 50. Note that, in FIG. 11, the mark 741 is omitted.

Correspondences between the components of the circuit of the electronic component 1 shown in FIG. 1 and the internal components of the stack 50 shown in FIG. 3B to FIG. 10A will now be described. First, the inductor L10 will be described. The inductor L10 is composed of the inductor conductor layers 562 and 572 and a through hole connecting these conductor layers.

Next, components of the first filter circuit 10 will be described. The inductor L11 is composed of the inductor conductor layers 681, 691, 701, 711, 721, and 731, and a plurality of through holes connecting these conductor layers. The inductor L12 is composed of the inductor conductor layers 702, 712, 722, and 732 and a plurality of through holes connecting these conductor layers. The inductor L13 is composed of the inductor conductor layers 571, 581, and 591 and a plurality of through holes connecting these conductor layers.

The capacitor C11 is composed of the conductor layers 532 and 542 and the dielectric layer 53 interposed between these conductor layers. The capacitor C12 is composed of the conductor layers 552, 563, and 573 and the dielectric layers 55 and 56 each interposed between two of these conductor layers. The capacitor C13 is composed of the conductor layers 542, 552, and 564 and the dielectric layers 54 and 55 each interposed between two of these conductor layers.

Next, components of the second filter circuit 20 will be described. The inductor L21 is composed of the inductor conductor layers 633, 643, 663, 673, 693, 703, 723, and 733 and a plurality of through holes connecting these conductor layers. The inductor L22 is composed of the inductor conductor layers 654, 664, 674, 714, 724, and 734 and a plurality of through holes connecting these conductor layers.

The capacitor C21 is composed of the conductor layers 533, 543, and 553 and the dielectric layers 53 and 54 each interposed between two of these conductor layers. The capacitor C22 includes a capacitance that is formed by the electrode 117, the conductor layer 543, and the dielectric layers 51 to 53 interposed between the electrode 117 and the conductor layer 543, and includes a floating capacitance that is generated between the electrode 117 and the electrodes 116, 118, and 119 close to one other. The capacitor C23 is composed of the conductor layers 553, 565, 574 and 582 and the dielectric layers 55 to 57 each interposed between two of these conductor layers.

Next, components of the third filter circuit 30 will be described. The inductor L31 is composed of the inductor conductor layers 635, 645, 665, 675, 695, 705, 725, and 735 and a plurality of through holes connecting these conductor layers. The inductor L32 is composed of the inductor conductor layers 521, 531, 541, 551, and 561 and a plurality of through holes connecting these conductor layers.

The capacitor C31 is composed of the conductor layers 592 and 601 and the dielectric layer 59 interposed between these conductor layers. The capacitor C32 is composed of the conductor layers 583 and 593 and the dielectric layer 58 interposed between these conductor layers. The capacitor C33 is composed of the conductor layers 575, 583, and 592 and the dielectric layers 57 and 58 each interposed between two of these conductor layers.

Next, components of the fourth filter circuit 40 will be described. The inductor L41 is composed of the inductor conductor layers 696, 706, 716, 726, and 736 and a plurality of through holes connecting these conductor layers. The inductor L42 is composed of the inductor conductor layers 697, 707, 717, 727, and 737 and a plurality of through holes connecting these conductor layers.

The inductor L43 is composed of the inductor conductor layers 688, 698, 708, 718, 728, and 738 and a plurality of through holes connecting these conductor layers. The inductor L44 is composed of the conductor layers 709 and 719, two through holes connecting the conductor layers 709 and 719, a plurality of through holes connecting the conductor layers 568 and 709, and a plurality of through holes connecting the conductor layers 577 and 709.

The capacitor C41 is composed of the conductor layers 544 and 554 and the dielectric layer 54 interposed between these conductor layers. The capacitor C42 is composed of the conductor layers 555 and 566 and the dielectric layer 55 interposed between these conductor layers. The capacitor C43 is composed of the conductor layers 522, 534, 545, 555, 567, and 576 and the dielectric layers 52 to 56 each interposed between two of these conductor layers.

The capacitor C44 is composed of the conductor layers 535 and 555 and the dielectric layers 53 and 54 interposed between these conductor layers. The capacitor C45 is composed of the conductor layers 545 and 556 and the dielectric layer 54 interposed between these conductor layers. The capacitor C46 is composed of the conductor layers 536 and 544 and the dielectric layer 53 interposed between these conductor layers.

The capacitor C47 is composed of the conductor layers 523 and 537 and the dielectric layer 52 interposed between these conductor layers. The capacitor C48 is composed of the conductor layers 537 and 546 and the dielectric layer 53 interposed between these conductor layers.

The capacitor C49 is composed of the conductor layers 708 and 718 and the dielectric layer 70 interposed between these conductor layers. The capacitor C50 is composed of the conductor layers 546, 557, 568, and 577 and the dielectric layers 54 to 56 each interposed between two of these conductor layers.

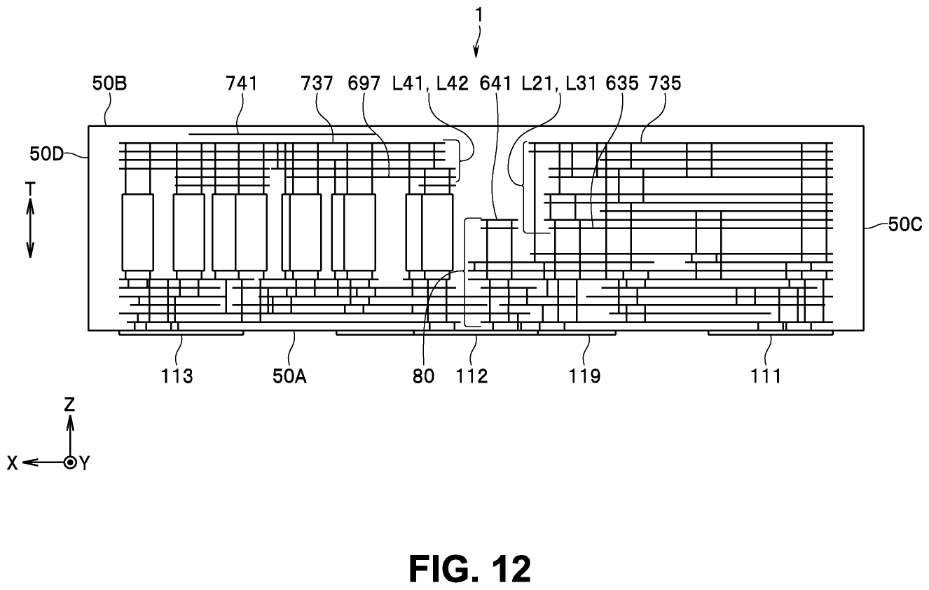

Next, structural features of the electronic component 1 according to the present embodiment will be described with reference to FIGS. 1 to 12. FIG. 12 is a side view showing an inside of the stack 50.

The electronic component 1 includes a shield structure 80 integrated with the stack 50. The shield structure 80 is composed of a plurality of conductors connected to the ground. In the present embodiment, the shield structure 80 is composed of the conductor layers 569, 631, and 641 and the through holes 52T1 to 52T3, 53T1 to 53T3, 54T1 to 54T3, 55T1 to 55T3, 56T1 to 56T3, 57T1 to 57T3, 58T1 to 58T3, 59T1 to 59T3, 60T1 to 60T3, 61T1 to 61T3, and 63T1 to 63T3.

The shield structure 80 is electrically connected to the electrodes 112, 116, 118, and 119 connected to the ground. Specifically, the through hole 52T1 of the shield structure 80 is electrically connected to the electrode 112 via the conductor layer 524 and the through hole 51T2. The through holes 52T2 and 52T3 of the shield structure 80 are electrically connected to the electrodes 116, 118, and 119 via the conductor layer 525 and the through holes 51T6, 51T8, and 51T9.

The shield structure 80 is arranged between the inductors L21 and L31 and the inductors L41 and L42 when viewed in the stacking direction T. Each of the inductors L21 and L31 corresponds to the “second inductor” in the present invention. Each of the inductors L41 and L42 corresponds to the “first inductor” in the present invention.

The inductor L21 includes the plurality of inductor conductor layers 633, 643, 663, 673, 693, 703, 723, and 733, the conductor layers being arranged at a certain interval in the stacking direction T. Here, among a plurality of conductor layers that constitute an inductor, a conductor layer arranged at a position closest to the first surface 50A of the stack 50 is referred to as a first conductor layer, and a conductor layer arranged at a position closest to the second surface 50B of the stack 50 is referred to as a second conductor layer. In the inductor L21, the conductor layer 633 corresponds to the first conductor layer, and the conductor layer 733 corresponds to the second conductor layer.

The inductor L31 includes the plurality of inductor conductor layers 635, 645, 665, 675, 695, 705, 725, and 735, the conductor layers being arranged at a certain interval in the stacking direction T. In the inductor L31, the conductor layer 635 corresponds to the first conductor layer, and the conductor layer 735 corresponds to the second conductor layer.

The inductor L41 includes the plurality of inductor conductor layers 696, 706, 716, 726, and 736, the conductor layers being arranged at a certain interval in the stacking direction T. In the inductor L41, the conductor layer 696 corresponds to the first conductor layer, and the conductor layer 736 corresponds to the second conductor layer.

The inductor L42 includes the plurality of inductor conductor layers 697, 707, 717, 727, and 737, the conductor layers being arranged at a certain interval in the stacking direction T. In the inductor L42, the conductor layer 697 corresponds to the first conductor layer, and the conductor layer 737 corresponds to the second conductor layer.

The shield structure 80 is arranged between the respective second conductor layers, in other words, the conductor layers 733, 735, 736, and 737 of the inductors L21, L31, L41, and L42 and the first surface 50A of the stack 50, in the stacking direction T.

The respective first conductor layers, in other words, the conductor layers 633 and 635, of the inductors L21 and L31 are arranged at a position closer to the first surface 50A than the respective first conductor layers, in other words, the conductor layers 696 and 697, of the inductors L41 and L42.

The shield structure 80 includes the conductor layer 641 that is a specific conductor closest to the second surface 50B of the stack 50. A distance between the respective first conductor layers, in other words, the conductor layers 633 and 635, of the inductors L21 and L31 and the conductor layer 641 of the shield structure 80 in the stacking direction T is shorter than a distance between the respective first conductor layers, in other words, the conductor layers 696 and 697, of the inductors L41 and L42 and the conductor layer 641 of the shield structure 80 in the stacking direction T. In the present embodiment, in particular, the conductor layer 641 of the shield structure 80 is arranged between the conductor layers 633 and 635 of the inductors L21 and L31 and the conductor layers 696 and 697 of the inductors L41 and L42, in the stacking direction T.

Each of the inductors L21, L31, L41, and L42 is wound around an axis extending in a direction parallel to the stacking direction T. Each of the conductor layers 631 and 641 of the shield structure 80 extends in a direction intersecting with the above-described axis. In the present embodiment, in particular, each of the conductor layers 631 and 641 extends in a direction parallel to the Y direction.

Next, the operation and effects of the electronic component 1 according to the present embodiment will be described. In the present embodiment, the shield structure 80 is arranged between the inductors L21, L31 and the inductors L41, L42 when viewed in the stacking direction T, and is arranged between the respective second conductor layers, in other words, the conductor layers 733, 735, 736, and 737, of the inductors L21, L31, L41, and L42 and the first surface 50A of the stack 50 in the stacking direction T. In the present embodiment, in particular, the respective first conductor layers, in other words, the conductor layers 633 and 635, of the inductors L21 and L31 are arranged at a position closer to the first surface 50A than the respective first conductor layers, in other words, the conductor layers 696 and 697, of the inductors L41 and L42. According to the present embodiment, the shield structure 80 allows magnetic coupling of leakage magnetic flux of each of the inductors L21 and L31 with the inductors L41 and L42 to be suppressed.

The present embodiment also allows generation of a floating capacitance between each of the inductors L21, L31, L41, and L42 and the shield structure 80 to be suppressed, as compared with a case where the specific conductor, in the shield structure 80, closest to the second surface 50B of the stack 50 is arranged at a position the same as that of the second conductor layer of each of the inductors L21, L31, L41, and L42 in the stacking direction T or a case where the specific conductor is arranged at a position closer to the second surface 50B than the second conductor layer.

In the present embodiment, a distance between the respective first conductor layers, in other words, the conductor layers 633 and 635, of the inductors L21 and L31 and the conductor layer 641 of the shield structure 80 in the stacking direction Tis shorter than a distance between the respective first conductor layers, in other words, the conductor layers 696 and 697, of the inductors L41 and L42 and the conductor layer 641 of the shield structure 80 in the stacking direction T. Thus, in the present embodiment, the conductor layer 641 of the shield structure 80 is arranged at a position closer to the first surface 50A of the stack 50 than the respective first conductor layers, in other words, the conductor layers 696 and 697, of the inductors L41 and L42. With this, the present embodiment can effectively suppress generation of a floating capacitance between each of the inductors L41 and L42 and the shield structure 80.

In the present embodiment, most of leakage magnetic flux that leaks from each of the inductors L41 and L42 toward the first surface 50A is prevented from entering inside each of the inductors L21 and L31 by the plurality of conductor layers constituting each of the inductors L21 and L31. With this, the present embodiment can suppress magnetic coupling of the inductors L41 and L42 with the inductors L21 and L31.

In the present embodiment, the second filter circuit 20 includes the inductor L21, the third filter circuit 30 includes the inductor L31, and the fourth filter circuit 40 includes the inductors L41 and L42. According to the present embodiment, magnetic coupling of the inductor L21 with the inductors L41 and L42 can be suppressed, allowing unnecessary coupling between the second filter circuit 20 and the fourth filter circuit 40 to be suppressed.

In the present embodiment, the second filter circuit 20 is connected to the first signal terminal 3 and the fourth filter circuit 40 is connected to the third signal terminal 5. According to the present embodiment, unnecessary coupling between the second filter circuit 20 and the fourth filter circuit 40 is suppressed, allowing isolation between the first signal terminal 3 and the third signal terminal 5 to be made large enough.

Similarly, according to the present embodiment, magnetic coupling of the inductor L31 with the inductors L41 and L42 can be suppressed, allowing unnecessary coupling between the third filter circuit 30 and the fourth filter circuit 40 to be suppressed and allowing isolation between the second signal terminal 4 connected to the third filter circuit 30 and the third signal terminal 5 to be made large enough.

In the example shown in FIG. 1, in particular, the third filter circuit 30 is a high-pass filter. The inductors L41 and L42 constitute a high-pass filter in the fourth filter circuit 40. The inductors L31, L41, and L42 have substantially the same function. The present embodiment can suppress occurrence of crosstalk between two circuits due to coupling between inductors having the same function.

As described above, the present embodiment allows desired characteristics to be achieved, while providing the shield structure 80.

Next, an example of characteristics of the electronic component 1 according to the present embodiment will be described. Here, characteristics of the electronic component 1 according to the present embodiment will be described comparing with characteristics of an electronic component of a comparative example. The electronic component of the comparative example has the same configuration as that of the electronic component 1 according to the present embodiment, except that no shield structure 80 is provided. Thus, a difference in characteristic between the electronic component 1 according to the present embodiment and the electronic component of the comparative example, which will be described below, is caused by the shield structure 80.

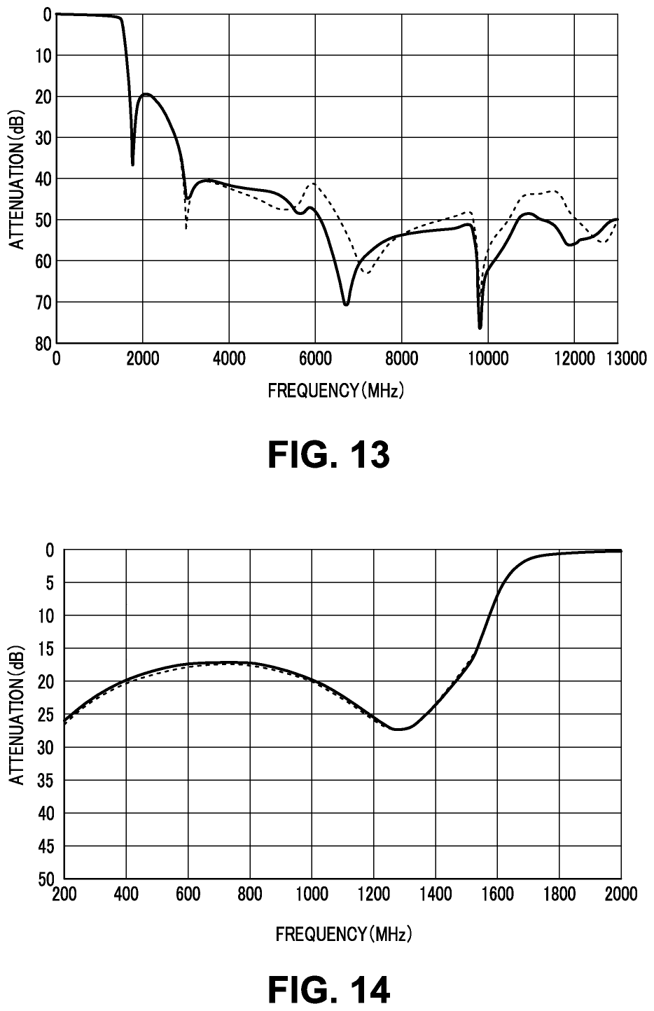

First, a characteristic related to the first signal terminal 3 will be described. FIG. 13 is a characteristic chart showing an example of pass attenuation characteristics between the common terminal 2 and the first signal terminal 3. FIG. 14 is a characteristic chart showing an example of return attenuation characteristics of the first signal terminal 3. In FIGS. 13 and 14, the horizontal axis indicates the frequency, and the vertical axis indicates the attenuation. In FIGS. 13 and 14, a curve of solid line indicates the attenuation of the electronic component 1 according to the present embodiment, and a curve of broken line indicates the attenuation of the electronic component of the comparative example. Note that, also in a drawing similar to FIG. 13 or 14 to be referenced to in the following description, the attenuation of the electronic component 1 according to the present embodiment is indicated with a solid line and the attenuation of the electronic component of the comparative example is indicated with a broken line.

In FIG. 13, a frequency domain where the pass attenuation has a value close to zero indicates the first passband. As seen from FIG. 13, in a frequency domain higher than the first passband, the pass attenuation of the electronic component 1 according to the present embodiment is larger than the pass attenuation of the electronic component of the comparative example.

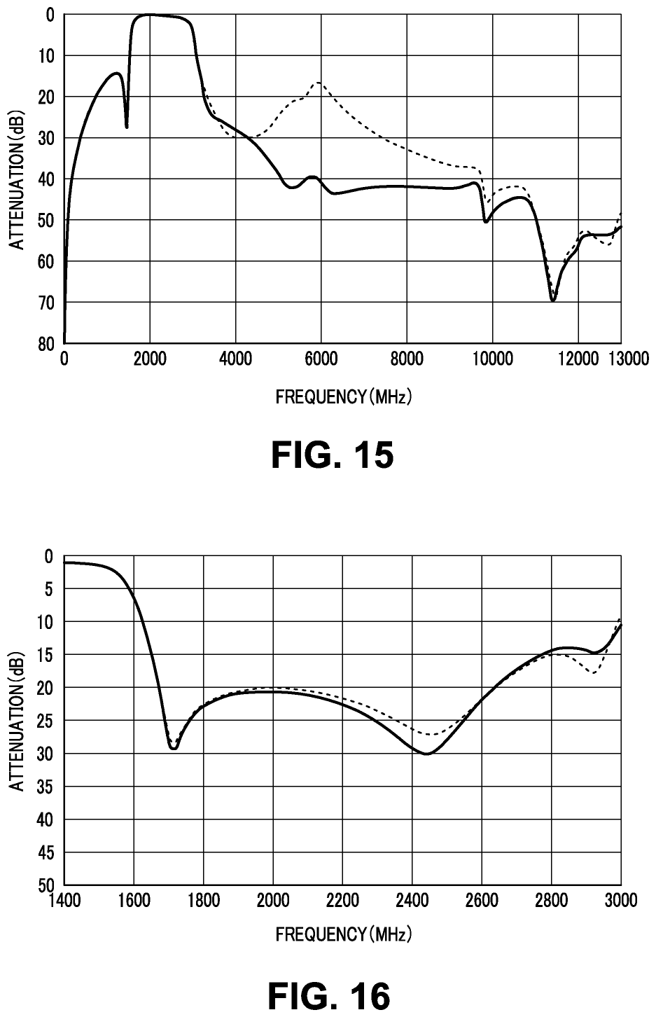

Next, a characteristic related to the second signal terminal 4 will be described. FIG. 15 is a characteristic chart showing an example of pass attenuation characteristics between the common terminal 2 and the second signal terminal 4. FIG. 16 is a characteristic chart showing an example of return attenuation characteristics of the second signal terminal 4. In FIGS. 15 and 16, the horizontal axis indicates the frequency, and the vertical axis indicates the attenuation. In FIG. 15, a frequency domain where the pass attenuation has a value close to zero indicates the second passband. As seen from FIG. 15, in a frequency domain higher than the second passband, the pass attenuation of the electronic component 1 according to the present embodiment is larger than the pass attenuation of the electronic component of the comparative example.

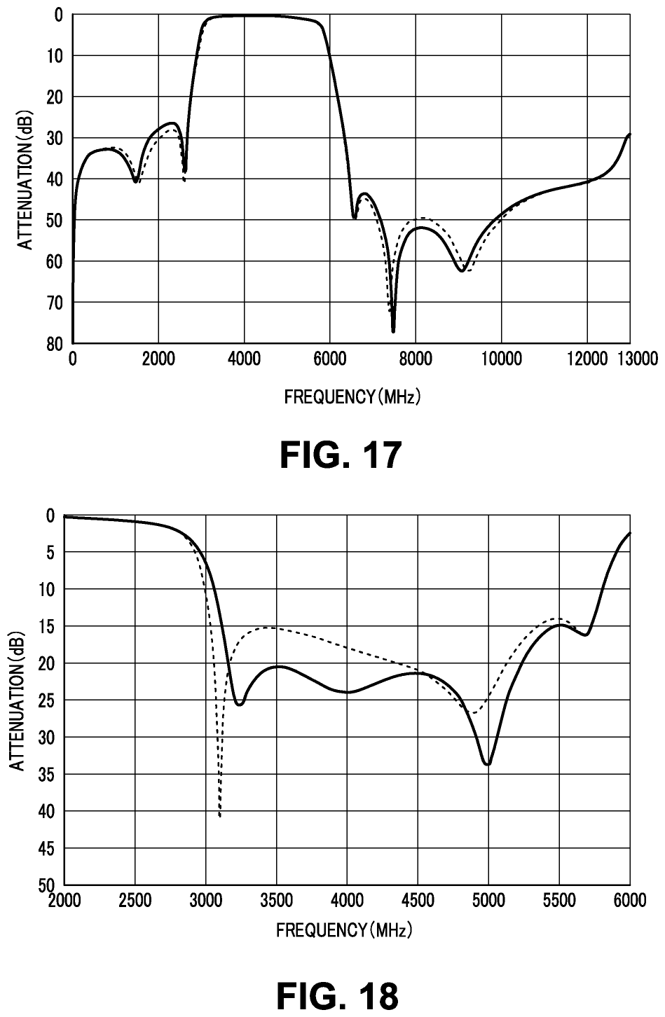

Next, a characteristic related to the third signal terminal 5 will be described. FIG. 17 is a characteristic chart showing an example of pass attenuation characteristics between the common terminal 2 and the third signal terminal 5. FIG. 18 is a characteristic chart showing an example of return attenuation characteristics of the third signal terminal 5. In FIGS. 17 and 18, the horizontal axis indicates the frequency, and the vertical axis indicates the attenuation. In FIG. 17, a frequency domain where the pass attenuation has a value close to zero indicates the third passband. As seen from FIG. 18, in the frequency domain in the third passband, the return attenuation of the electronic component 1 according to the present embodiment is larger than the return attenuation of the electronic component of the comparative example.

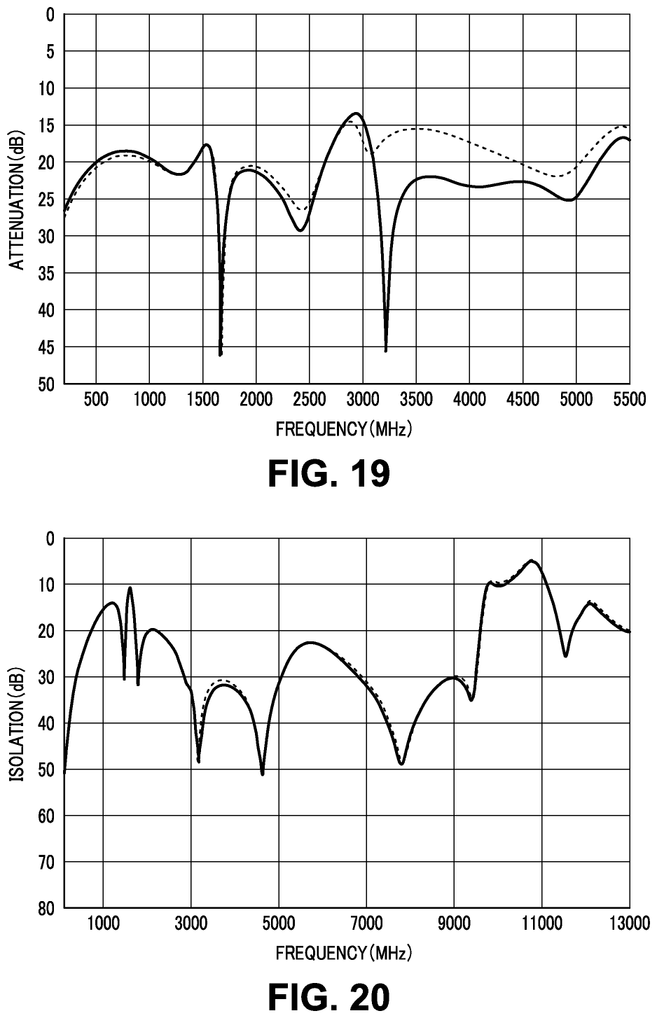

Next, a characteristic related to the common terminal 2 will be described. FIG. 19 is a characteristic chart showing an example of return attenuation characteristics of the common terminal. In FIG. 19, the horizontal axis indicates frequency, and the vertical axis indicates the attenuation. As seen from FIG. 19, in the frequency domain in the third passband (see FIG. 17), the return attenuation of the electronic component 1 according to the present embodiment is larger than the return attenuation of the electronic component of the comparative example.

Next, isolation will be described. Isolation I between two signal terminals may be calculated using power P1 of a high frequency signal input to one of the two signal terminals and power P2 of a signal output from the other of the two signal terminals, by Equation (1) as below.

$$I = 10 log ( P 2 / P 1 ) \qquad ( 1 )$$

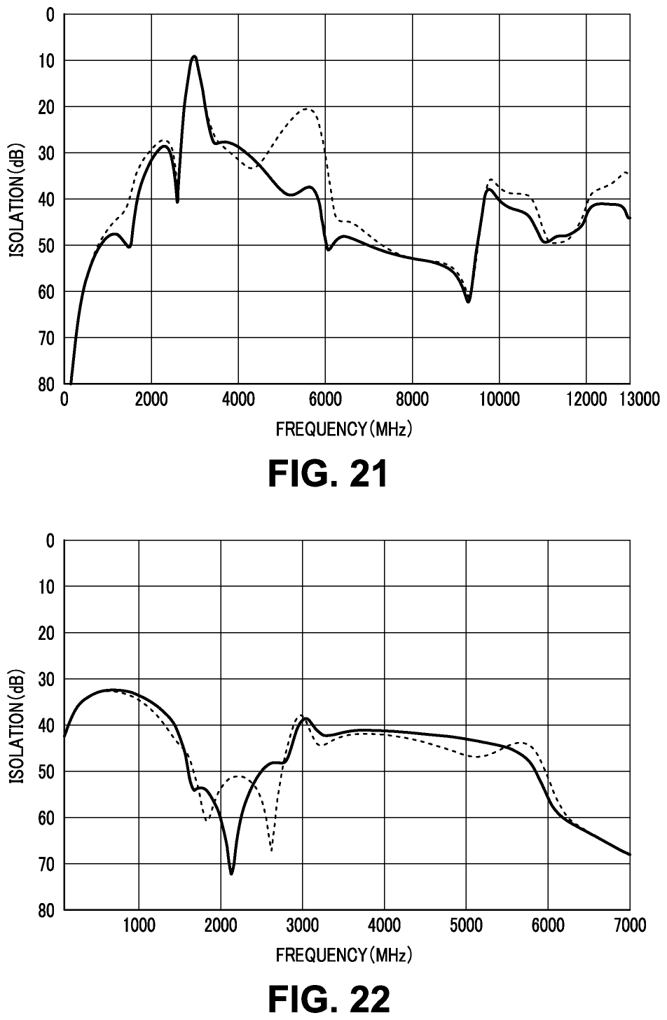

FIG. 20 shows isolation between the first signal terminal 3 and the second signal terminal 4. FIG. 21 shows isolation between the second signal terminal 4 and the third signal terminal 5. FIG. 22 shows isolation between the third signal terminal 5 and the first signal terminal 3. In FIGS. 20 to 22, the horizontal axis indicates the frequency, and the vertical axis indicates the isolation. In FIGS. 20 to 22, a curve of solid line indicates the isolation of the electronic component 1 according to the present embodiment, and a curve of broken line indicates the isolation of the electronic component of the comparative example.

As seen from FIG. 20, the isolation between the first signal terminal 3 and the second signal terminal 4 has little difference between the electronic component 1 according to the present embodiment and the electronic component of the comparative example. As seen from FIG. 21, the isolation between the second signal terminal 4 and the third signal terminal 5 of the electronic component 1 according to the present embodiment is larger than that of the electronic component of the comparative example, in the frequency domain in the third passband (see FIG. 17). As seen from FIG. 22, in the frequency domain higher than the first passband (see FIG. 13), the isolation between the third signal terminal 5 and the first signal terminal 3 of the electronic component 1 according to the present embodiment has a peak larger than that of the electronic component of the comparative example.

Note that the present invention is not limited to the foregoing embodiment, and various modifications may be made thereto. For example, the multilayer electronic component of the present invention is not limited to the branching filter as triplexer, may be a branching filter such as diplexer, quadplexer, or the like.

The specific conductor, of the shield structure 80, closest to the second surface 50B of the stack 50 may be at a position the same as that of the respective first conductor layers, in other words, the conductor layers 633 and 635, of the inductors L21 and L31 in the stacking direction T, or may be at a position closer to the second surface 50B than the conductor layers 633 and 635.

As described above, a multilayer electronic component of the present invention includes a first inductor, a second inductor, a shield structure, and a stack that integrates the first inductor, the second inductor, and the shield structure, the stack including a plurality of dielectric layers stacked together. The stack includes a first surface and a second surface located at both ends in a stacking direction of the plurality of dielectric layers. Each of the first inductor and the second inductor includes a plurality of inductor conductor layers, the plurality of inductor conductor layers being arranged at a certain interval in the stacking direction. The plurality of inductor conductor layers include a first conductor layer closest to the first surface and a second conductor layer closest to the second surface. The shield structure is arranged between the first inductor and the second inductor when viewed in the stacking direction, and is arranged between the second conductor layer and the first surface in the stacking direction.

In the multilayer electronic component of the present invention, the first conductor layer of the first inductor and the first conductor layer of the second inductor may be arranged at positions different from each other in the stacking direction. The first conductor layer of the second inductor may be arranged at a position closer to the first surface than the first conductor layer of the first inductor. The shield structure may include a specific conductor closest to the second surface. A distance between the first conductor layer of the second inductor and the specific conductor in the stacking direction may be shorter than a distance between the first conductor layer of the first inductor and the specific conductor in the stacking direction.

In the multilayer electronic component of the present invention, each of the first inductor and the second inductor may be wound around an axis extending in a certain direction. The shield structure may include a specific conductor that extends in a direction intersecting with the certain direction.

In the multilayer electronic component of the present invention, the shield structure may include a plurality of through holes and at least one shield conductor layer.

The multilayer electronic component of the present invention may further include a ground electrode provided on a surface of the stack and connected to the ground. The shield structure may be electrically connected to the ground electrode.

The multilayer electronic component of the present invention may further include a first signal terminal, a second signal terminal, a first circuit connected to the first signal terminal and including the first inductor, and a second circuit connected to the second signal terminal and including the second inductor. The first signal terminal, the second signal terminal, the first circuit, and the second circuit may be integrated with the stack. The multilayer electronic component of the present invention may further include a common terminal integrated with the stack. The first circuit may be provided between the common terminal and the first signal terminal, in the circuit configuration. The second circuit may be provided between the common terminal and the second signal terminal, in the circuit configuration. The first circuit and the second circuit may constitute a branching filter.

Obviously, many modifications and variations of the present invention are possible in the light of the above teachings. Thus, it is to be understood that, within the scope of the appended claims and equivalents thereof, the invention may be practiced in other embodiments than the foregoing most preferable embodiment.

What is claimed is:

1. A multilayer electronic component comprising:
a first inductor;
a second inductor;
a shield structure; and
a stack that integrates the first inductor, the second inductor, and the shield structure, the stack including a plurality of dielectric layers stacked together, wherein
the stack includes a first surface and a second surface located at both ends in a stacking direction of the plurality of dielectric layers,
each of the first inductor and the second inductor includes a plurality of inductor conductor layers, the plurality of inductor conductor layers being arranged at a certain interval in the stacking direction,
the plurality of inductor conductor layers include a first conductor layer closest to the first surface and a second conductor layer closest to the second surface, and
the shield structure is arranged between the first inductor and the second inductor when viewed in the stacking direction, and is arranged between the second conductor layer and the first surface in the stacking direction.

2. The multilayer electronic component according to claim 1, wherein
the first conductor layer of the first inductor and the first conductor layer of the second inductor are arranged at positions different from each other in the stacking direction.

3. The multilayer electronic component according to claim 2, wherein
the first conductor layer of the second inductor is arranged at a position closer to the first surface than the first conductor layer of the first inductor,
the shield structure includes a specific conductor closest to the second surface, and
a distance between the first conductor layer of the second inductor and the specific conductor in the stacking direction is shorter than a distance between the first conductor layer of the first inductor and the specific conductor in the stacking direction.

4. The multilayer electronic component according to claim 1, wherein
each of the first inductor and the second inductor is wound around an axis extending in a certain direction, and
the shield structure includes a specific conductor that extends in a direction intersecting with the certain direction.

5. The multilayer electronic component according to claim 1, wherein
the shield structure includes a plurality of through holes and at least one shield conductor layer.

6. The multilayer electronic component according to claim 1, further comprising:
a ground electrode provided on a surface of the stack and connected to a ground, wherein
the shield structure is electrically connected to the ground electrode.

7. The multilayer electronic component according to claim 1, further comprising:
a first signal terminal;
a second signal terminal;
a first circuit connected to the first signal terminal and including the first inductor; and
a second circuit connected to the second signal terminal and including the second inductor, wherein
the first signal terminal, the second signal terminal, the first circuit, and the second circuit are integrated with the stack.

8. The multilayer electronic component according to claim 7, further comprising:
a common terminal integrated with the stack, wherein
the first circuit is provided between the common terminal and the first signal terminal, in a circuit configuration,
the second circuit is provided between the common terminal and the second signal terminal, in the circuit configuration, and
the first circuit and the second circuit constitute a branching filter.
